(19) United States
(12) Patent Application Publication
(10) Pub. No.: US 2011/0039116 A1
(43) Pub. Date: Feb. 17, 2011

(54) COLORED PLATING STRUCTURE AND METHOD THEREOF

(76) Inventor: Peng-Jung CHUANG, Hsinchu County (TW)

Correspondence Address: Muncy, Geissler, Olds & Lowe, PLLC, 4000 Legato Road, Suite 310, FAIRFAX, VA, 22033, US

(21) Appl. No.: 12/847,146

(22) Filed: Jul. 30, 2010

(30) Foreign Application Priority Data
Aug. 11, 2009 (TW) 98126897
Aug. 14, 2009 (TW) 98215001

(51) Int. Cl. B32B 15/04; B05D 3/12; B05D 3/10; B05D 3/02; C23C 14/02; B32B 9/04

(52) U.S. Cl. 428/457; 427/294; 427/195; 427/295; 427/296; 428/411.1

(57) ABSTRACT

The present invention discloses a colored plating structure and a method thereof. Firstly, a color layer and a medium layer are sequentially coated on the surface of a workpiece. The medium is used to integrate the succeeding layer with the workpiece. Next, a plated layer is coated on the medium layer via a vacuum-plating method. Thereby, the present invention not only exempts the plated products from the dull metal color and simple brightness variation but also provides diversified colors and lusters for the plated products. The present invention provides an exceptional surface quality the conventional technology is hard to achieve.

### BACKGROUND OF THE INVENTION

1. Field of the Invention

The present invention relates to a colored plating structure and a method thereof, particularly to a colored plating structure and a method thereof, which can provide diversified colors and lusters for a vacuum-plated workpiece.

2. Description of the Related Art

Plating is a surface treatment process to provide luster and esthetic appearance for a product, improve the corrosion-resistance of the product and prolong the service life of the product, whereby is promoted the value of the product.

Plating includes zinc-plating, chromium-plating, nickel-plating, copper-plating, gold-plating, silver-plating, lead-plating and alloy-plating, which respectively provide different colors and lusters for products. The conventional plating technology is less likely to provide diversified variations of colors and lusters but can only modify the brightness of the metal layer via varying the formula of the plating material. Sometimes, a colored clear lacquer is sprayed on the plated workpiece to provide color for the workpiece and obtain a colored plated product. However, the color provided by the method is dull and likely to mask the luster of the plated metal.

### SUMMARY OF THE INVENTION

The primary objective of the present invention is to provide a colored plating structure and a method thereof, which can set the plated products free from the primitive dull metal color without comprising the luster of the metal, and which can present diversified tints in response to the variation of illumination conditions and light incident angles, wherefore it has very high commercial potential.

To achieve the abovementioned objective, the present invention proposes a colored plating structure, which comprises a primer paint layer, a color paint layer, a medium layer and a plated layer that are sequentially coated on the surface of a workpiece, whereby the dull color of the plated metal is controllably converted into one of diversified tints.

The present invention also proposes a method for fabricating a colored plating structure. Firstly, a primer paint is sprayed on the ground and polished workpiece to cover the scratches and form a smooth primer paint layer facilitating the succeeding spraying operation. Next, a color paint is uniformly sprayed on the primer paint layer to present the required color. The color paint contains a pigment, which is selected from a group consisting of red pigments, blue pigments, yellow pigments, green pigments, golden pigments, silver pigments, and the combinations thereof. Next, a medium layer is uniformly coated on the color paint layer. The medium layer will integrate the workpiece with a plated layer. Next, the abovementioned plated layer is coated on the workpiece via a vacuum-plating method, wherein the workpiece is placed in a vacuum furnace, and wherein argon atoms impact a metal target to sputter the metal on the workpiece. Then, a clear lacquer is sprayed on the workpiece to form a protective layer protecting the plated layer from abrasion.

Below, the embodiments are described in detail in cooperation with the drawings to make easily understood the objectives, characteristics, and efficacies of the present invention.

### BRIEF DESCRIPTION OF THE DRAWINGS

FIGS. 1A-1F are diagrams schematically showing the process of fabricating a colored plating structure according to one embodiment of the present invention.

### DETAILED DESCRIPTION OF THE INVENTION

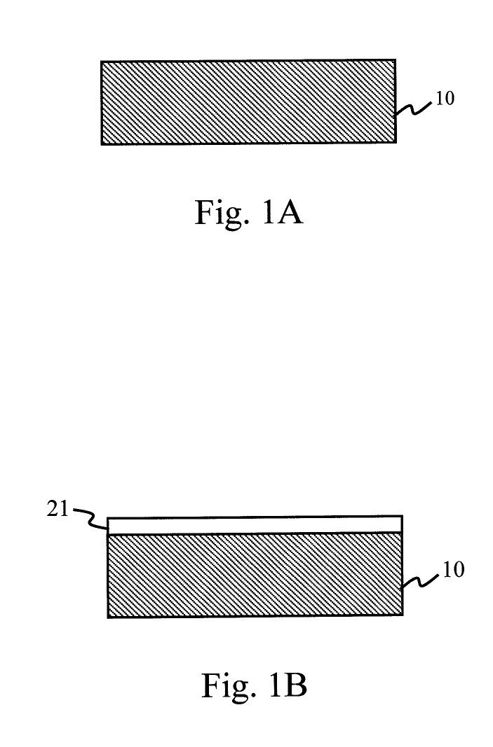

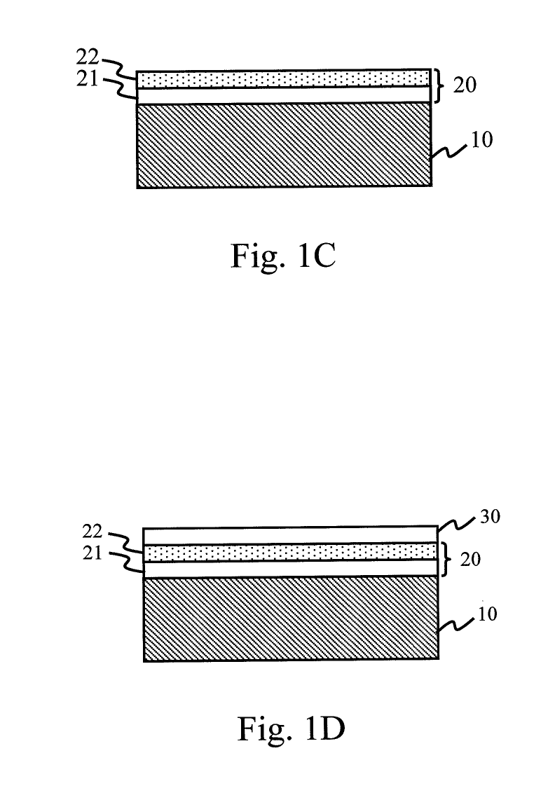

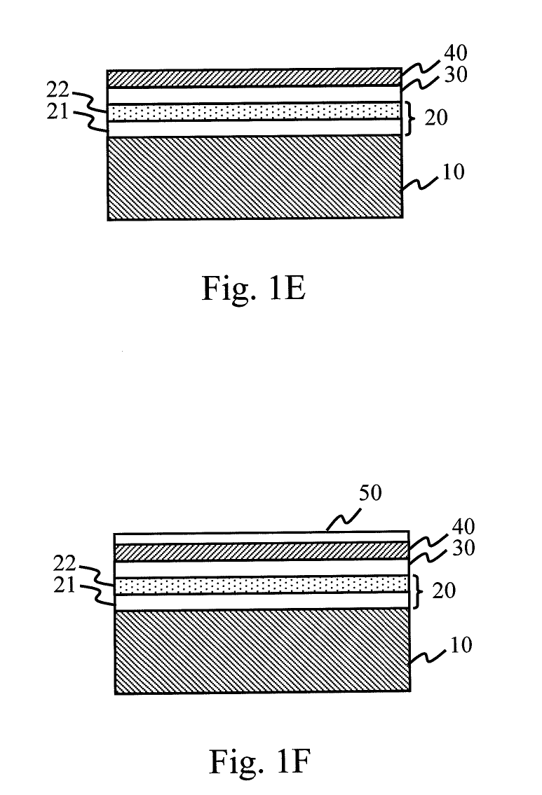

Refer to FIGS. 1A-1F diagrams schematically showing the process of fabricating a colored plating structure according to one embodiment of the present invention.

As shown in FIG. 1A, firstly is provided a workpiece 10, which has been pre-processed. The material of the workpiece 10 may be but is not limited to a plastic or a metal. Therefore, the present invention can apply to a wide field.

The pre-processing process of the workpiece 10 includes grinding-polishing steps and cleaning steps. The cleaning steps are described below. Firstly, the workpiece 10 is flushed with overflowed water. Secondly, the grease on the surface of the workpiece 10 is removed with a degreasing agent having a concentration of 15-23PP in water having a temperature of 40-50° C. Thirdly, the workpiece 10 is flushed with overflowed water to remove the residual degreasing agent. Fourthly, the workpiece 10 is flushed with a chemical conversion coating agent solution having a concentration of 0.8-1.2PP at an ambient temperature to form a film on the surface of the workpiece 10, wherein the film can prevent the workpiece 10 from oxidization. Fifthly, the workpiece 10 is flushed with water to remove the residual chemical conversion coating agent. Sixthly, the workpiece 10 is flushed with RO (Reverse Osmosis) water having a resistivity of 0-20 μs. Then, the workpiece 10 is dried in an oven at a temperature of 180-200° C. Thus are completed the cleaning steps. Next, a synthetic resin powder is sprayed on the surface of the cleaned workpiece 10. Next, the workpiece 10 is baked at a temperature of 215° C. The powdered synthetic resin is melted into liquid at the high temperature. After the workpiece 10 is taken out from the oven, the liquid solidifies into a solid-state film (not shown in the drawings) adhering to the surface of the workpiece 10. The solid-state film has a thickness of 110-150 m.

After the solid-state film is done, a color layer 20 is coated on the solid-state film. The color layer 20 includes a gray primer paint layer 21 and a color paint layer 22. As shown in FIG. 1B, a gray primer paint is sprayed on the surface of the workpiece 10 to form a smooth gray primer paint layer 21. The gray primer paint contains 2% of a gray pigment, 52% of solvents and 46% of acrylic resins. The gray primer paint layer 21 is dried at a temperature of 80° C.

Next, as shown in FIG. 1C, a color paint is sprayed on the gray primer paint layer 21 to form the color paint layer 22. The color paint primarily contains toluene, xylene, organic solvents, synthetic resins and a pigment. The pigment is selected from a group consisting of red pigments, blue pigments, yellow pigments, green pigments, golden pigments, silver pigments, and the combinations thereof. The present invention does not limit the components of the pigment and the ratio of the components. The pigment may contain various components by any ratio. Therefore, the components and the ratio thereof will not be listed herein. The color paint layer 22 is baked at an oven at a temperature of 160° C.

Next, as shown in FIG. 1D, a medium paint is sprayed on the color paint layer 22 to for a medium layer 30. The medium layer 30 is used to stabilize the underneath layers and increase the density of the vacuum-plated layer, whereby the succeeding layers can firmly adhere to the workpiece 10. The medium paint primarily contains toluene, xylene, organic solvents, and synthetic resins. For example, the medium paint may contain 55% of acrylic resins, 5% of hydrocarbon solvents and 40% of aromatic solvents. The medium layer 30 is baked in an oven at a temperature of 190° C.

Next, as shown in FIG. 1E, the workpiece 10 is hanged in a vacuum furnace, and a vacuum-plating is undertaken inside the vacuum furnace, wherein argon atoms impact a metal target inside the vacuum furnace to form a uniform plated metal layer 40 on the surface of the workpiece 10.

After the plated metal layer 40 is done, a clear lacquer is sprayed on the workpiece 10 to form a protective layer 50. The protective layer 50 is used to protect the plated metal layer 40 and increase the luster of the workpiece 10. The clear lacquer primarily contains 42% of acrylic resins and 58% of organic solvents. The clear lacquer is baked in an oven at a temperature of 160° C. Thereby is completed the colored plating structure of the present invention.

In conclusion, the present invention proposes a colored plating structure and a method thereof. The present invention is distinct from the conventional technology that can only vary the brightness of the plated layer and that has to spray a colored clear lacquer on the plated layer to obtain a colored plated product. Contrarily, the present invention exempts the plated products from the primitive dull metal color without comprising the luster of the metal. The present invention can present diversified tints in response to the variation of illumination conditions and light incident angles. Thereby, the present invention provides an exceptional surface quality the conventional technology is hard to achieve. Further, the present invention can apply to various fields. Therefore, the present invention is a novel plating technology having very high commercial potential.

The embodiments described above are only to exemplify the present invention but not to limit the scope of the present invention. Any equivalent modification or variation according to the spirit of the present invention is to be also included within the scope of the present invention, which is based on the claims sated below.

What is claimed is:

1. A colored plating structure comprising
a workpiece;
a color layer coated on a surface of said workpiece;
a medium layer coated on a surface of said color layer; and
a plated layer vacuum-plated on a surface of said medium layer.

2. The colored plating structure according to claim 1, wherein said workpiece is made of a plastic material or a metallic material.

3. The colored plating structure according to claim 1, wherein said color layer includes a primer paint layer and a color paint layer, wherein a primer paint is coated on said surface of said workpiece to form said primer paint layer having a smooth surface, and wherein a color paint is coated on a surface of said primer paint layer to said color paint layer presenting a specified color.

4. The colored plating structure according to claim 3, wherein said primer paint is a gray primer paint containing 2% of a gray pigment, 52% of solvents and 46% of acrylic resins.

5. The colored plating structure according to claim 3, wherein said color paint contains 52% of solvents, 43% of acrylic resins and 5% of a pigment, and wherein said pigment is selected from a group consisting of red pigments, blue pigments, yellow pigments, green pigments, golden pigments, silver pigments, and combinations thereof.

6. The colored plating structure according to claim 1, wherein said medium layer contains 55% of acrylic resins, 5% of hydrocarbon solvents and 40% of aromatic solvents.

7. The colored plating structure according to claim 1 further comprising
a protective layer coated on a surface of said plated layer and used to protect said plated layer.

8. The colored plating structure according to claim 7, wherein said protective layer is made of a clear lacquer containing 42% of acrylic resins and 58% of organic solvents.

9. A method for fabricating a colored plating structure comprising steps:
coating a color layer on a surface of a workpiece;
coating a medium layer on a surface of said color layer; and
vacuum-plating a plated layer on a surface of said medium layer.

10. The method for fabricating a colored plating structure according to claim 9 further comprising a step of performing a pre-processing treatment on said workpiece before coating said color layer, wherein said pre-processing treatment includes grinding and finishing said workpiece.

11. The method for fabricating a colored plating structure according to claim 10 further comprising a step of cleaning said workpiece after grinding and finishing said workpiece.

12. The method for fabricating a colored plating structure according to claim 11, wherein said step of cleaning said workpiece further comprises steps:
washing said surface of said workpiece;
using a degreasing agent to remove grease on said surface of said workpiece;
cleaning said degreasing agent remaining on said surface of said workpiece;
flushing said surface of said workpiece with a chemical conversion coating agent to form a protective film; and
flushing said surface of said workpiece with pure water.

13. The method for fabricating a colored plating structure according to claim 11 further comprising a step of spraying powders of a plurality of synthetic resins on said surface of said workpiece after cleaning said workpiece, baking said powders of said synthetic resins into a liquid, and cooling down said liquid to form a solid-state film adhering to said surface of said workpiece, wherein said solid-state film has a thickness of 110-150 μm.

14. The method for fabricating a colored plating structure according to claim 9, wherein said workpiece is made of a plastic material or a metallic material.

15. The method for fabricating a colored plating structure according to claim 9, wherein said step of coating said color layer further comprises steps:
spraying a primer paint on said surface of said workpiece to form a primer paint layer having a smooth surface; and
spraying a color paint on a surface of said primer paint layer to form a color paint layer presenting a specified color.

16. The method for fabricating a colored plating structure according to claim 15, wherein said primer paint is a gray primer paint containing 2% of a gray pigment, 52% of solvents and 46% of acrylic resins.

17. The method for fabricating a colored plating structure according to claim 15, wherein said color paint contains 52% of solvents, 43% of acrylic resins and 5% of a pigment, and wherein said pigment is selected from a group consisting of red pigments, blue pigments, yellow pigments, green pigments, golden pigments, silver pigments, and combinations thereof

18. The method for fabricating a colored plating structure according to claim 9, wherein said medium layer contains 55% of acrylic resins, 5% of hydrocarbon solvents and 40% of aromatic solvents.

19. The method for fabricating a colored plating structure according to claim 9 further comprising a step of coating a protective layer on a surface of said plated layer to protect said plated layer.

20. The method for fabricating a colored plating structure according to claim 19, wherein said protective layer is made of a clear lacquer containing 42% of acrylic resins and 58% of organic solvents.
